(19) United States
(12) Patent Application Publication
(10) Pub. No.: US 2020/0043408 A1
(43) Pub. Date: Feb. 6, 2020

(54) THIN FILM-BASED SPHERICAL OR HEMISPHERICAL DISPLAY DEVICE

(71) Applicant: Michael Foody, Saratoga, CA (US)

(72) Inventor: Michael Foody, Saratoga, CA (US)

(73) Assignee: Global Imagination, Inc., Campbell, CA (US)

(21) Appl. No.: 16/530,720

(22) Filed: Aug. 2, 2019

Related U.S. Application Data
(60) Provisional application No. 62/714,223, filed on Aug. 3, 2018.

(51) Int. Cl. G09G 3/3225

(52) U.S. Cl. CPC G09G 3/3225; H04W 4/80; G09G 2300/0408; G09G 2380/02

(57) ABSTRACT

The present invention refers to a display device of a general spherical display surface, which comprises a general spherical body that is spherical or hemispherical or any form in between, a layer of displaying film covering substantially the whole surface of the body, and an electronic driver circuitry which is connected to the layer of displaying film for powering and driving the displaying film. The layer of displaying films is thin and cut, for instance, in a plurality of pieces in banana shape, half banana shape, hexagonal shape, diamond shape, triangle shape, soccer ball, or even in sphere or hemisphere of an integral part. Alternatively, the present invention may be a globe display device which has internally installed driving circuitry and wireless communication device mounted inside of the globe. The display device is capable of communicating with any Smartphone with an APP for operation, or a separate control device.

### FIELD OF THE INVENTION

This invention relates to spherical or hemispherical display apparatus, and more particularly it relates to a spherical or hemispherical display apparatus made of thin flexible display films, such as AMOLED film or the like, attached to the surface of a spherical or hemispherical body.

### BACKGROUND OF THE INVENTION

Currently, spherical or hemispherical display devices have gained public recognition for displaying information, such as scientific, educational, virtual reality, entertainment, advertising, etc. For displaying information on a sphere or hemisphere, there are a number of approaches: front or rear projection in different configurations, or LED panels. Such approaches are costly, offer limited resolution, and are limited in scale. In order to achieve high brightness and resolution, the necessary projectors and lenses for front or rear projection on a sphere or hemisphere are expensive. And while LED panels are bright, their comparative resolution is low. In addition, viewers expectations have become more demanding—they expect the level of brightness, quality, and interactivity on a sphere or hemisphere that they now find routinely on their phones. To date, interactivity on spherical and hemispherical surfaces has been implemented using cameras, sometimes with IR flood lighting. These approaches are expensive and require significant tuning and adjustment. As a result, an affordable, high resolution, bright, interactive spherical or hemispherical display is still sought.

### SUMMARY OF THE INVENTION

The present invention is a solution for spherical or hemispherical display systems that eliminates the requirement for front or rear projection systems, and for LED panels. It offers high resolution and low cost, while still being able to achieve a touch-interactive surface. Here, the term of “spherical” should refer to any shapes that are proportion of a spherical, such as, one third, two third, three fourth, or any portion of a general spherical shape, including hemispherical shape. According to the present invention, a spherical or hemispherical display device comprises a spherical or hemispherical body, a plurality of pieces of displaying films covering substantially the whole surface of the body, and necessary electronics driver circuitry and software. The driver circuitry and software which together drive the pieces of display films, communicate with a computer CPU, which determines the imagery to be displayed on the sphere or hemisphere. The computer CPU may retrieve or calculate the imagery to be displayed using a wide variety of techniques. The spherical or hemispherical body is a solid body and generally hollow inside. In addition, when touch interactivity is required on the display, additional driver circuitry and software may communicate with the CPU about touch-interactive events and gestures, which the CPU interprets and uses programming to determine the corresponding actions.

According to the present invention, the CPU may or may not be integral to the device. The two may communicate in a wired or in a wireless fashion, locally or over a network. The CPU may be in a traditional computer, in a mobile device, in a “compute stick”, or in any other forms.

According to the invention, a variety of adhesives may be used to attach the display film to the solid spherical or hemispherical body to cover almost the whole body. The adjacent pieces of films may be aligned or mated with each other at their respective corresponding edges, or have their respective edges overlapping with each other slightly, or have an edge of one piece of film bend and embedded in a recess formed on the surface of the body and a corresponding edge of another piece of film extending over the embedded edge in the recess.

According to the invention, the electronics may be attached to the film using a “right angle connector,” or a connector with a small radius bend, which goes through an opening in the solid body to which the film is attached, enabling different pieces of film to be mated together. Alternately, the electronics may be hidden at the base of the unit where the sphere or hemisphere are supported. In addition, pieces of film may overlap, thus hiding seams, and electronics from the viewer.

The present invention is illustrated or can be better understood through the accompanying drawings, and is defined in the accompanying claims.

### BRIEF DESCRIPTION OF DRAWINGS OF THE INVENTION

FIG. 1A is an illustration of the spherical display device of the present invention.

FIG. 1B shows schematically the general structure of the spherical display device in cross-section.

FIGS. 2A and 2B show the first embodiment of the present invention which has a plurality of pieces of banana shaped displaying films covering the whole surface of the spherical body.

FIGS. 2C and 2D show a proportion of a general sphere on the first embodiment of the present invention having a plurality of pieces of general banana shaped display firms covering the surface of the general spherical body.

FIGS. 3A and 3B show the second embodiment of the present invention which has a plurality of pieces of banana shaped displaying films in halves in two sets, one set of which covers the upper surface of the spherical body, and the other set of which covers the lower surface of the spherical surface of the spherical body.

FIG. 4 shows the third embodiment of the present invention which has a plurality of pieces of hexagonal shape displaying films covering the whole surface of the spherical body.

FIG. 5 shows the fourth embodiment of the present invention which has a plurality of pieces of hexagonal shape displaying films in two sets covering the whole surface of the spherical body.

FIGS. 6A, 6B, and 6C shows the various connections of the display films

FIGS. 7A to 7D illustrate a location of the electronics for driving the display films and various connections or wiring arrangements.

FIGS. 8A and 8B are examples of an electronic circuitry that may be used, as a choice, for powering and driving the thin displaying films, and CPU for processing images and contents.

FIG. 9 shows a portable or compact global or spherical display device which is a globe, having driving electronics and a mobile device or communication device inside the body.

### DETAILED DESCRIPTION OF THE INVENTION:

As is well known, flexible AMOLED films and other similar films may be used for curved displaying surfaces of TV sets or Smartphone or the like, and each kind of displaying films may have specific characteristics. For the present invention, it is desired to choose a displaying film or films that would be suitable to be curved to cover spherical or hemispherical surfaces of a globe in different sizes, and that can be cut or manufactured into various shapes to cover the spherical surface of the globe more smoothly. It would be preferred to have the displaying films cut or manufactured into, for instance, a plurality of pieces in banana shape, half banana shape, hexagonal shape, diamond shape, triangle shape, soccer ball, or formed in hemisphere as an integral part. The ones of most interest are the ones listed above or shown in the drawings, i.e., individual banana-shaped films, the same, yet cut in half at the equator; and hexagon, pentagon.

In any event, some electronics would be required for providing images of contents for displaying on the spherical or global display device. Such electronics may be based on “edge electronics.” Depending on the shape of the displaying films, those “electronics” may be provided at the bottom of the globe or somewhere at the connecting point or edges of the displaying films.

Also, depending on the needs or applications of the global or spherical displaying device, the electronics may be just a “connecting device” for communication with mobile devices or remote devices, or just any computers via wired or wireless, or have telecommunication capacity with telecommunication providers.

The driver electronics for film-based displays are well known, and are specific to the type of film being utilized. These electronics provide power to the elements of the film, and provide “addressability”—the ability to determine to specific color and brightness of every single pixel individually.

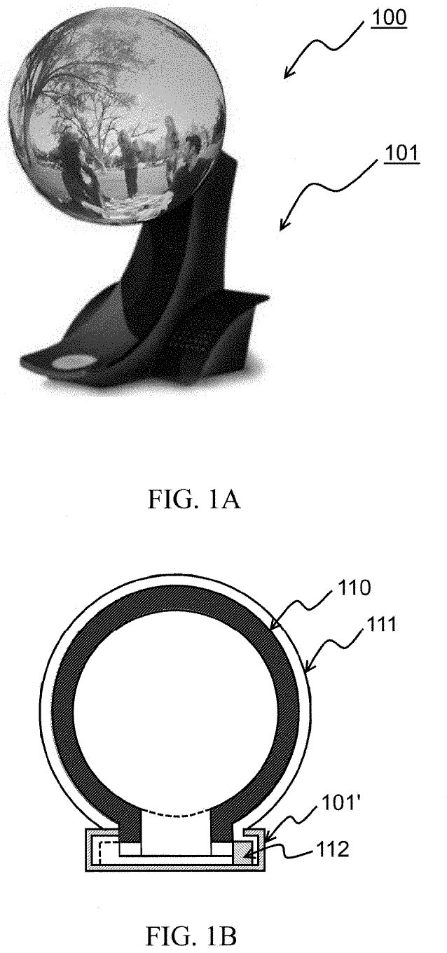

FIG. 1A shows schematically a global or spherical display device. It comprises a spherical or global displaying screen 100, and a base 101 for positioning the global or spherical displaying device. The necessary electronics may be provided and/or accommodated in the base. FIG. 1B illustrates schematically the global or spherical display device in cross-section, and it shows a layer of thin displaying film 111 covering over the whole surface of a solid and hollow spherical body 110, which sits or is provided on a base 101′. The base contains at least the necessary electronics 112 for powering and driving the displaying film and is connected with the thin displaying film at an appropriate location; and the base 101′ may also contain the computer or processing unit that may provide any desired images and contents for displaying on the spherical display device, i.e., on the thin displaying film or films.

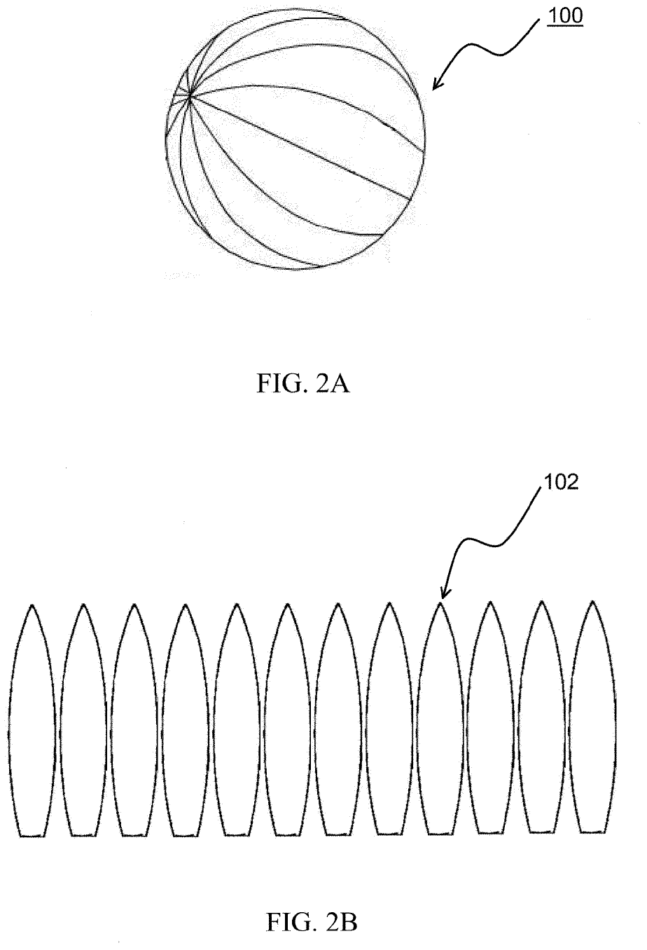

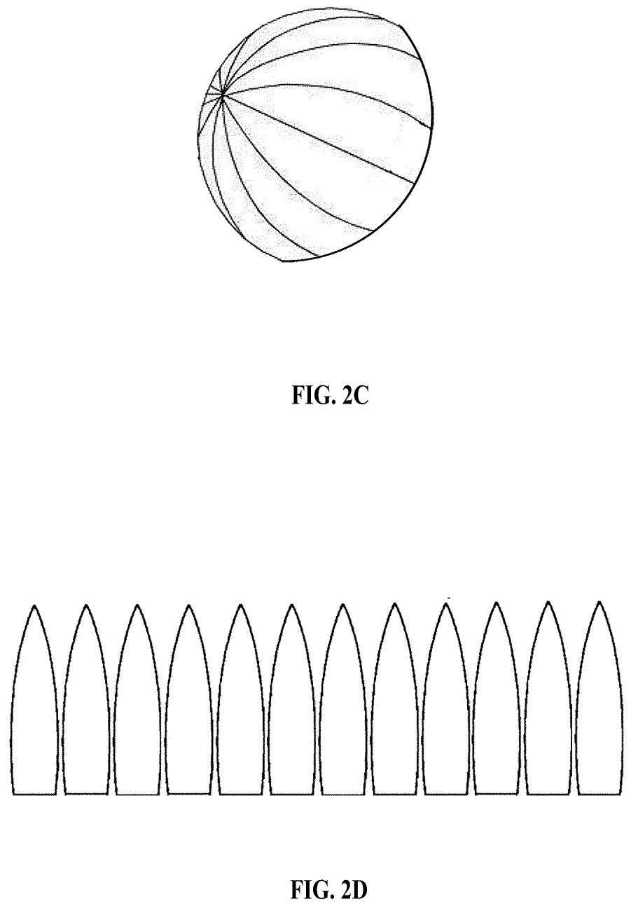

In FIGS. 2A and 2B, the banana shaped displaying films 102 are shown, and each piece is almost in a whole banana shape. In FIGS. 2C and 2D, the banana shaped display films 103 are shown for a shape that's partially between a sphere and a hemisphere, illustrative of a possible proportion of a general sphere; while FIGS. 3A and 3B shows each piece of the displaying film 102a and 102b in a half banana shape. FIG. 2B illustrates how the thin displaying films may be cut in banana shape, and FIG. 2A shows those banana shaped pieces being attached on the surface of the solid spherical body to form a globe or sphere display device 100, i.e., a displaying screen. The global or spherical display device 100 may then be mounted to a base which may contain the necessary electronics and processing unit for providing the desired displaying images and contents in a way as illustrated in FIG. 1B.

FIG. 3A shows an upper part of a spherical display device 100a, such as the one shown in FIG. 2A, and FIG. 3B shows a lower part of the spherical display device 100b. In such an arrangement, each piece of the thin displaying films is in a half banana shape. As it can be understood, the necessary electronics may be provided between the two halves or hemispherical parts, and it may be in a shape of circular connecting belt 101″ as illustrated in FIG. 3A. Alternatively, the upper hemisphere may serve individually as a hemispherical display device 100a, with the connecting belt 101″ being a base to house the driver electronics 112 and possibly computer or processing unit for displaying images and contents. The connection of the films and the electronics may be similar as seen in FIG. 1B.

In any event, the edges of those pieces of the thin films shown in the above embodiments of FIGS. 2A-2D, 3A and/or 3B may be corresponding flat or bezel edges so that the adjacent pieces of films may meet or engage with each other smoothly. The electronics for powering and driving the films are provided generally towards to the lower or bottom portion of the globe and provided in the base; but they may be provided between the upper and lower hemispheres, depending on the desired designs of the globe display device.

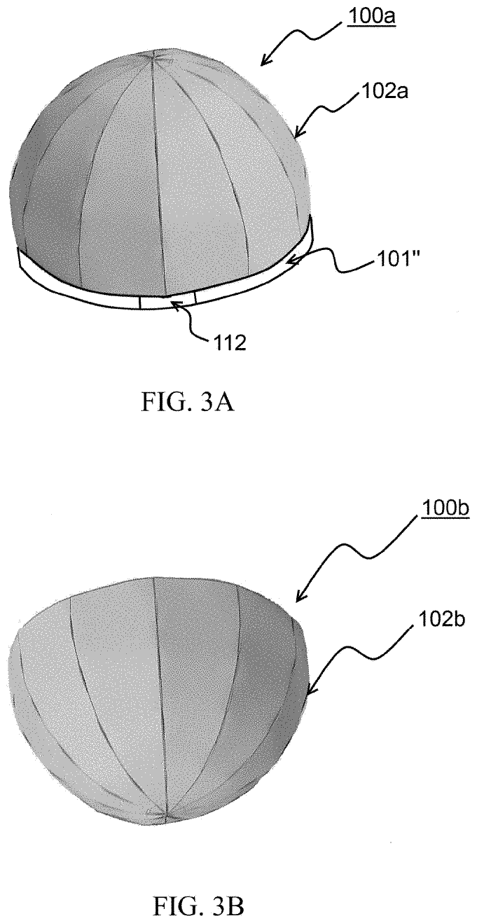

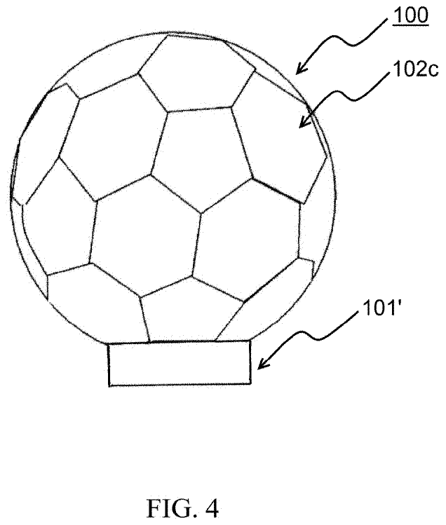

In FIGS. 4 and 5, a plurality of pieces of displaying films 102c are shown, each in hexagonal shape. FIG. 4 shows a spherical display device with such hexagonal shape pieces of film 102c, that is mounted on a base 101′. FIG. 5 shows a spherical display device with such hexagonal shape pieces of film 102c, that is two-halves or two hemispheres, between which there is a connecting belt 101″ provided, similar to FIGS. 3A and 3B. Again, it may be a hemispherical display device, if so desired, that is, the lower hemisphere may be omitted, while only the upper hemisphere serves as a displaying screen 100 and the connecting belt portion 101″ is the base for accommodating the electronics and/or processing unit. The connection of the pieces of films may be either edge-to-edge, or they may overlap slightly to hide any seams. Again, those pieces of displaying films cover substantially the whole spherical surface in case of a globe or sphere or cover the whole hemispherical surface in case of a hemisphere.

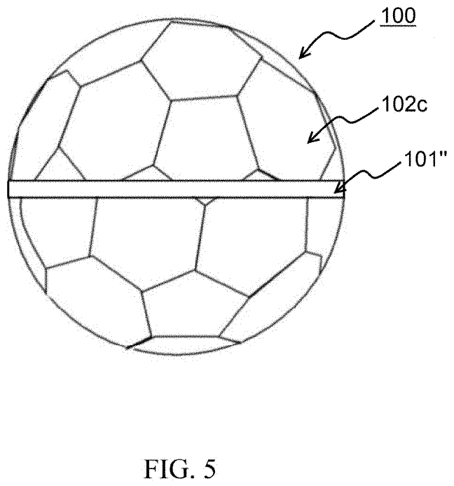

Depending on what shapes of those pieces are, it is always possible to make them to cover substantially the entire surfaces of a globe or sphere, or hemisphere. The shapes of banana and maybe hexagon are the ones described here; but it may be understood that the shapes of diamond, pentagon, triangle, or some irregular pieces may also be used. However, the key is how they may be connected effectively and maybe preferably for having smoother or seamless appearance. FIGS. 6A, 6B, and 6C are the examples of possible ways of connection. FIG. 6A is edge-to-edge connection of which the pieces of films 102x, 102y may have to be glued to the surface of the spherical or hemispherical body 110 of the display device with their edges aligned with each other. FIG. 6B shows the adjacent pieces of films 102x, 102y having their edges overlapping, which may show bulges all over the globe, and may not be so smooth as normally required, but it could form a specific pattern, if so desired, over the spherical surface of the display globe. Nonetheless, FIG. 6C may show a connection that would be more preferred if a smooth surface of the globe is desired, and it needs to form corresponding bezel recesses or grooves 114 over the spherical or hemispherical surfaces of the body 110 of the display globe, i.e., corresponding to the shape of the pieces of the display films so that one of the adjacent pieces will have the edge bended or curved into the bezel recess or groove 114, while the other piece has the edge overlap the hidden edge in the bezel recess or groove. This will assure a smoother transition of a piece of film to the adjacent piece of film of the layer of thin displaying films.

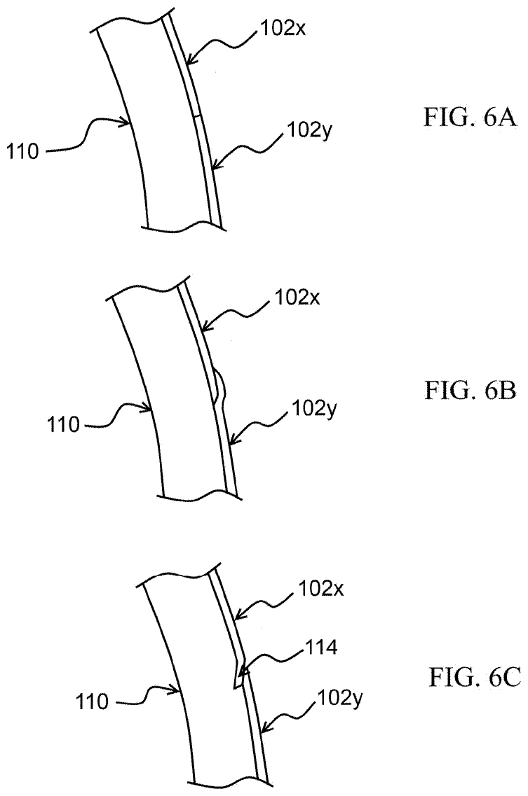

FIG. 7A shows the electronics 112 mounted in the base 101′ as enlarged view from FIG. 1B, and FIGS. 7B to 7D show, respectively, the connection or wiring from the electronics 112 for powering or illuminating and driving the thin displaying films of the globe. As stationed on the base of the globe, the electronics 112 are provided usually at the bottom of the globe, seating on the base 101′. The base may accommodate any sizeable circuity for connecting with computer or images and contents processing unit or just mobile communication device for communicating with remote computer or processing unit or any images and contents devices, if not provided in the base, as seen in FIG. 7A. It would be the same for the base of a hemisphere display device. Alternatively, the electronics may be provided between two hemispheres, i.e., the connecting belt portion as described above, such as in a circular groove around the globe, and thus the base may be replaced with just a small diameter pole or column for the purpose of support or standing (not shown).

FIGS. 7B to 7D shows various ways of wiring 113 of the electronics 112 to the pieces of thin displaying films 102x, but all of the wirings are provided through the hollow spherical or hemispherical body. It may be understood that those wirings may be embedded and affixed somehow to the interior surfaces of the hollow spherical or hemispherical body (not shown). However, it can be understood that the respective wirings should go through individual holes 116 that are provided on the solid spherical or hemispherical body 110, preferably uniformly throughout the body (not shown). FIG. 7B shows that an electronic wiring 113 goes through one of the through-holes 116 and connects an end of one piece of the films, while the end of the other adjacent piece of the films 102y is provided to mate and be aligned with the one piece of the films 102x. FIG. 7C shows that an electronic wiring 113 goes through one of the through-holes 116 and connects an end of one piece of the films 102x, while the end of the other adjacent piece of the films 102y overlaps the connected end of the one piece of the films 102x. FIG. 7D shows that an electronic wiring 113 goes through one of the through-holes 116 and connects an end of one piece of the films 102x around a bezel edge of the through-hole 116 of the solid body 110, while the end of the other adjacent piece of the films 102y overlaps the connected end of the one piece of the films 102x. Again, all of the electronic wirings 113 are provided and affixed somehow against the interior surface of the spherical or hemispherical body, on which provided are a plurality of recesses or grooves and through-holes 116, preferably uniformly in predetermined patterns or positions.

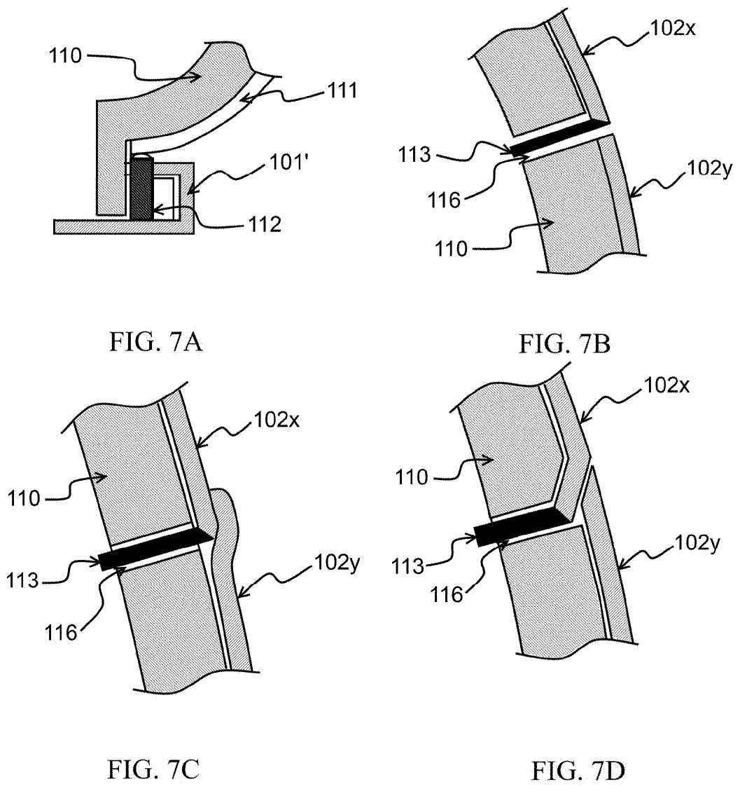

FIGS. 8A and 8B show an example of electronics for powering and driving the thin displaying films. It can be any suitable electronic circuitry to perform such functions as available for AMOLED film or the like, and an example of CPU for processing the images and contents for displaying on the screen of films. As exemplified in FIG. 8B, a microprocessor unit (MPU) 105, or microcontroller unit (MCU) provides information to the OLED controller via a serial or parallel interface 106. The OLED controller 107, typically incorporates a frame buffer which stores the information to be displayed on the AMOLED glass or film panel 111. The OLED controller, in turn, drives the image signals connected directly to the panel.

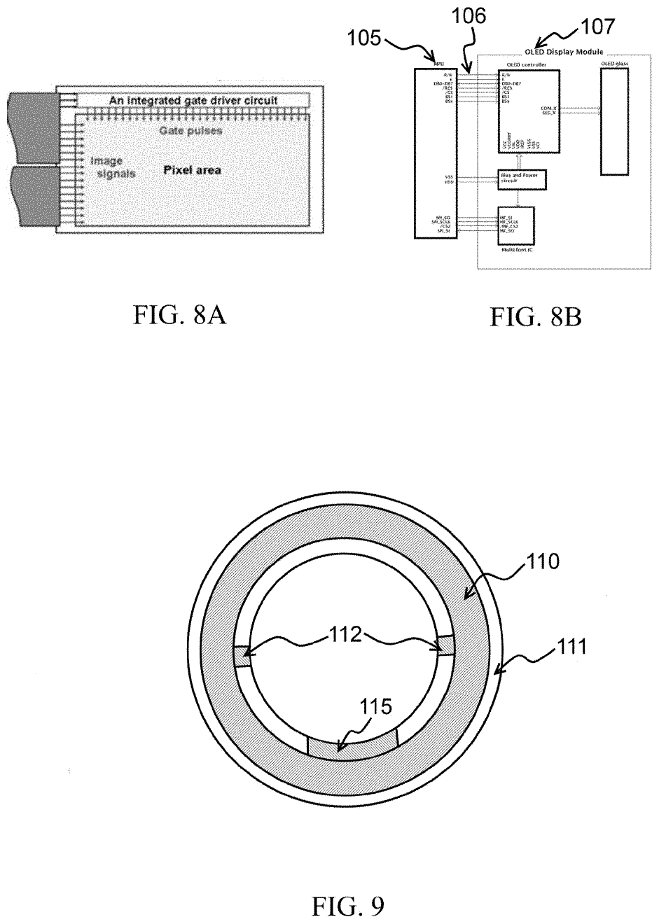

FIG. 9 shows a portable or compact global or spherical display device 100a which is a globe, having driving electronics 112 and a mobile device or communication device 115 inside the body 110. It means no base or any circular connecting belt needed as described in the above embodiments. In this situation, the electronics may be provided inside of the globe, i.e., inside the hollow spherical solid body, and may contain some kind of images or contents processing unit that store and provide desired images and contents for displaying over the spherical displaying screen or surface of the globe. The integral globe may also contain a wireless communication device. It could communicate wirelessly through WiFi or Bluetooth or similar technology. If it is a mobile device inside the globe, it could then communicate with any remote station, database, or control device, etc., through telecommunication network. Any Smartphone or the like may have an App for controlling the operation of the globe display device. Alternatively, a separate controller may be provided for operating the same.

What I claim is:

1. A display device of a general spherical display surface, comprising a general spherical body that is spherical or hemispherical or in between, a layer of displaying film covering substantially the whole surface of the body, and an electronic driver circuitry which is connected to the layer of displaying film for powering and driving the displaying film.

2. A display device of claim 1, further comprising a base that is arranged to accommodate at least the electronic driver circuitry.

3. A display device of claim 2, wherein said base is arranged to accommodate a unit capable of establishing wireless and Bluetooth connection or wireless telecommunication with an outside or remote information processing unit for providing displaying images and contents to the layer of displaying film.

4. A display device of claim 1, wherein the layer of displaying film is of a plurality of pieces of displaying films, each of which is generally in a banana shape in case of a spherical display device, and the plurality of pieces of displaying films are arranged to be adjacent with one another so as to cover substantially the whole spherical surface of the spherical body.

5. A display device of claim 1, wherein the layer of displaying film is of a plurality of pieces of displaying films in two sets, each of which is generally in a half banana shape, thereby forming an upper half and a lower half of the layer of displaying film in case of a spherical display device, and the plurality of pieces of displaying films of each set are arranged to be adjacent with one another so as to cover substantially the whole surface of one of the upper and lower halves of the spherical body.

6. A display device of claim 1, wherein the layer of displaying film is of a plurality of pieces of displaying films, each of which is generally in a half banana shape in case of a hemispherical display device, and the plurality of pieces of displaying films are arranged to be adjacent with one another so as to cover substantially the whole surface of the hemispherical body.

7. A display device of claim 1, wherein the layer of displaying film is of a plurality of pieces of displaying films, each of which is generally in a hexagon shape or part of a hexagon shape in case of a spherical display device, and the plurality of pieces of displaying films are arranged to be adjacent with one another so as to cover substantially the whole spherical surface of the spherical body.

8. A display device of claim 1, wherein the layer of displaying film is of a plurality of pieces of displaying films in two sets, each of which is generally in a hexagon shape or part of a hexagon shape, thereby forming an upper half and a lower half of the layer of displaying film in case of a spherical display device, and the plurality of pieces of displaying films of each set are arranged to be adjacent with one another so as to cover substantially the whole surface of one of the upper and lower halves of the spherical body.

9. A display device of claim 1, wherein the layer of displaying film is of a plurality of pieces of displaying films, each of which is in a hexagon shape or part of a hexagon shape in case of a hemispherical display device, and the plurality of pieces of displaying films are arranged to be adjacent with one another so as to cover substantially the whole surface of the hemispherical body.

10. A display device of claim 1, wherein said body is a spherical body that is capable of at least housing wiring arrangement from the electronic driver circuitry to the layer of displaying film.

11. A display device of claim 10, wherein said spherical body has at least a unit capable of establishing wireless and blue tooth connection or wireless telecommunication with an outside or remote information processing unit for providing displaying images and contents to the layer of displaying film.

12. A display device of claim 4, wherein said spherical body is capable of at least housing wiring arrangement from the electronic driver circuitry to the plurality of pieces of displaying films and has at least a unit capable of establishing wireless and blue tooth connection or wireless telecommunication with an outside or remote information processing unit for providing displaying images and contents to the layer of displaying film.

13. A display device of clam 12, where said spherical body is a hollow body.

14. A display device of claim 7, wherein said spherical body is capable of at least housing wiring arrangement from the electronic driver circuitry to the plurality of pieces of displaying films and has at least a unit capable of establishing wireless and blue tooth connection or wireless telecommunication with an outside or remote information processing unit for providing displaying images and contents to the layer of displaying film.

15. A display device of claim 1, wherein said layer of displaying film is AMOLED film.

16. A display device of claim 1, wherein said electronic driver circuity is implemented as an integrated circuit.

17. A display device of claim 1, wherein the layer of displaying film is of a plurality of pieces of displaying films, each of which is shaped identically.

18. A globe display device of a spherical display surface, comprising a spherical body, a layer of displaying film covering the whole surface of the body, an electronic driver circuitry which is connected to the layer of displaying film for powering and driving the displaying film, and a communication device that is capable of communicating wirelessly with a control device outside of the globe display device for operation thereof.

19. A globe display device of claim 18, wherein the control device is a separate controller for controlling the operation of the globe display device.
